(19) United States
(12) Patent Application Publication
(10) Pub. No.: US 2025/0142907 A1
(43) Pub. Date: May 1, 2025

(54) SEMICONDUCTOR DEVICE INCLUDING VERTICAL CHANNEL HAVING TUBE SHAPE

(71) Applicant: Samsung Electronics Co., Ltd., Suwon-si (KR)

(72) Inventors: Changhyun KIM, Suwon-si (KR); Kyung-Eun BYUN, Suwon-si (KR); Minsu SEOL, Suwon-si (KR); Junyoung KWON, Suwon-si (KR); Huije RYU, Suwon-si (KR); Eunkyu LEE, Suwon-si (KR); Yeonchoo CHO, Suwon-si (KR)

(73) Assignee: Samsung Electronics Co., Ltd., Suwon-si (KR)

(21) Appl. No.: 18/643,087

(22) Filed: Apr. 23, 2024

(30) Foreign Application Priority Data
Oct. 31, 2023 (KR) 10-2023-0148428

(51) Int. Cl. H01L 29/10; H01L 29/06

(52) U.S. Cl. CPC H10D 62/314; H10D 62/122

(57) ABSTRACT

A semiconductor device may include a substrate, a vertical channel, a gate electrode, and a conductive layer. The vertical channel may have a tube shape extending in a direction perpendicular to a surface of the substrate. The gate electrode may face the vertical channel with an outer insulating layer therebetween on an outer circumferential surface of the vertical channel. The conductive layer may face the vertical channel with an inner insulating layer therebetween on an inner circumferential surface of the vertical channel.

### CROSS-REFERENCE TO RELATED APPLICATION

This application is based on and claims priority under 35 U.S.C. § 119 to Korean Patent Application No. 10-2023-0148428, filed on Oct. 31, 2023, in the Korean Intellectual Property Office, the disclosure of which is incorporated by reference herein in its entirety.

### BACKGROUND

### 1. Field

The disclosure relates to a semiconductor device including a tube shape vertical channel.

### 2. Description of the Related Art

With the increased integration degree of semiconductor devices, various structures have been suggested to reduce a plane area occupied by each unit device. A transistor is a semiconductor device with an electric switching function and is employed in various integrated circuit (IC) devices including memories, driving ICs, logic devices, etc. To increase the integration degree of IC devices, a space occupied by a transistor has been significantly reduced. Due to this, the channel length of a transistor has been decreased, and the thickness of layers constituting the transistor has been reduced. Accordingly, research to reduce the size of the transistor while maintaining the desired performance thereof has been conducted.

### SUMMARY

Provided is a semiconductor device capable of improving an integration degree of unit devices.

Additional aspects will be set forth in part in the description which follows and, in part, will be apparent from the description, or may be learned by practice of the presented embodiments of the disclosure.

According to an embodiment of the disclosure, a semiconductor device may include a substrate, a vertical channel having a tube shape extending from the substrate in a first direction perpendicular to a surface of the substrate, an outer insulating layer on an outer circumferential surface of the vertical channel, a gate electrode facing the vertical channel with the outer insulating layer between the gate electrode and the vertical channel, an inner insulating layer on an inner circumferential surface of the vertical channel, and a conductive layer in the vertical channel and facing the vertical channel with the inner insulating layer between the conductive layer and the vertical channel.

In some embodiments, the gate electrode may surround an outer circumference of the vertical channel.

In some embodiments, the conductive layer may face the gate electrode.

In some embodiments, the semiconductor device may further include a source electrode and a drain electrode. The source electrode and the drain electrode each may be electrically connected to the vertical channel. The source electrode and the drain electrode may be apart from each other in the first direction.

In some embodiments, the gate electrode may be between the source electrode and the drain electrode.

In some embodiments, the vertical channel may include a transition metal dichalcogenide (TMD) material.

In some embodiments, the TMD material may include at least one of MoS₂, MoSe₂, MoTe₂, WS₂, WSe₂, WTe₂, ZrS₂, ZrSe₂, HfS₂, HfSe₂, NbSe₂, and ReSe₂.

In some embodiments, the vertical channel may include polysilicon.

In some embodiments, the semiconductor device may further include a source electrode and a drain electrode electrically connected to the vertical channel; and a vertical channel transistor array including a plurality of vertical channel transistor structures. The plurality of vertical channel transistor structures may be arranged in a two-dimensional (2D) manner on a plane perpendicular to the first direction. At least one vertical channel transistor structure among the plurality of vertical channel transistor structures may include the vertical channel, the outer insulating layer, the gate electrode, the inner insulating layer, the conductive layer, and the source electrode and the drain electrode electrically connected to the vertical channel.

In some embodiments, the vertical channel transistor array may include a plurality of vertical channel transistor arrays stacked in the first direction with an isolation layer therebetween.

According to an embodiment of the disclosure, a semiconductor device may include a substrate; a vertical channel having a tube shape extending from the substrate in a first direction perpendicular to a surface of the substrate, a lateral surface of the vertical channel including an opening, the lateral surface of the vertical channel perpendicular to the first direction; an outer insulating layer on an outer circumferential surface opposite to the opening of the vertical channel; a first gate electrode facing the vertical channel with the outer insulating layer between the first gate electrode and the vertical channel; an inner insulating layer on an inner circumferential surface on a side of the opening of the vertical channel; and a second gate electrode facing the vertical channel with the inner insulating layer between the second gate electrode and the vertical channel.

In some embodiments, the semiconductor device may further include a source electrode and a drain electrode. The source electrode and the drain electrode each may be electrically connected to the vertical channel and may be spaced apart from each other in the first direction.

In some embodiments, the first gate electrode may be between the source electrode and the drain electrode.

In some embodiments, the first gate electrode and the second gate electrode may face each other with the vertical channel between the first gate electrode and the second gate electrode.

In some embodiments, the vertical channel may include a TMD material.

In some embodiments, the TMD material may include at least one of MoS₂, MoSe₂, MoTe₂, WS₂, WSe₂, WTe₂, ZrS₂, ZrSe₂, HfS₂, HfSe₂, NbSe₂, and ReSe₂.

In some embodiments, the vertical channel may include polysilicon.

In some embodiments, the semiconductor device may further include a source electrode and a drain electrode electrically connected to the vertical channel; and a vertical channel transistor array including a plurality of vertical channel transistor structures arranged in a two-dimensional (2D) manner on a plane perpendicular to the first direction. At least one vertical channel transistor structure among the plurality of vertical channel transistor structures may include the vertical channel, the outer insulating layer, the first gate electrode, the inner insulating layer, the second gate electrode, and the source electrode and the drain electrode electrically connected to the vertical channel.

In some embodiments, the vertical channel transistor array may include a plurality of pairs of vertical channel transistor structures. At least one of the plurality of pairs of vertical transistor structures may include a first vertical channel transistor having the opening and a second vertical channel transistor having the opening. The opening of the first vertical channel transistor may face the opening of the second vertical channel transistor.

In some embodiments, the vertical channel transistor array may include a plurality of vertical channel transistor arrays stacked in the first direction with an isolation layer therebetween.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of a semiconductor device according to an embodiment;

FIG. 2 is a cross-sectional view of the semiconductor device of FIG. 1 taken along line D13-D13′, according to an embodiment;

FIG. 3 is a cross-sectional view of the semiconductor device of FIG. 1 taken along line D12-D12′, according to an embodiment;

FIGS. 4A and 4B are diagrams each illustrating an example of a cross-section of a vertical channel illustrated in FIG. 1;

FIG. 5 is a schematic plan view of a semiconductor device according to an embodiment;

FIG. 6 is a schematic side view of a semiconductor device according to an embodiment;

FIGS. 7A to 7H are diagrams each illustrating an example of a manufacturing method of a vertical channel having a tube shape;

FIG. 8 is a schematic cross-sectional view of a semiconductor device according to an embodiment, which corresponds to FIG. 2;

FIG. 9 is a schematic cross-sectional view of a semiconductor device according to an embodiment, which corresponds to FIG. 3;

FIGS. 10A and 10B are diagrams each illustrating an example of a cross-section of the vertical channel illustrated in FIG. 1;

FIG. 11 is a schematic plan view of a semiconductor device according to an embodiment; and

FIGS. 12 and 13 are conceptual diagrams each schematically illustrating a device architecture applicable to an electronic apparatus according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

Hereinafter, embodiments will be described in detail with reference to the accompanying drawings. In the drawings, like reference numerals in the drawings denote like elements, and sizes of components in the drawings may be exaggerated for clarity and convenience of explanation. Meanwhile, embodiments described below are provided only as an example, and thus can be embodied in various forms.

It will be understood that when a component is referred to as being “on” or “over” another component, the component can be directly on, under, on the left of, or on the right of the other component, or can be on, under, on the left of, or on the right of the other component in a non-contact manner. An expression used in the singular encompasses the expression of the plural, unless it has a clearly different meaning in the context. When a portion “includes” an element, another element may be further included, rather than excluding the existence of the other element, unless otherwise described.

The use of the terms “a” and “an” and “the” and similar referents in the context of describing embodiments (especially in the context of the following claims) are to be construed to cover both the singular and the plural. The operations of all methods described herein can be performed in any suitable order unless otherwise indicated herein or otherwise clearly contradicted by context, and embodiments are not limited to the described order of the operations.

Moreover, the terms “part,” “module,” etc. refer to a unit processing at least one function or operation, and may be implemented by a hardware, a software, or a combination thereof.

The connecting lines, or connectors shown in the various figures presented are intended to represent example functional relationships and/or physical or logical couplings between the various elements, and thus it should be noted that many alternative or additional functional relationships, physical connections or logical connections may be present in a practical device.

The use of any and all examples, or example language provided herein, is intended merely to better illuminate technical ideas and does not pose a limitation on the scope of embodiments unless otherwise claimed.

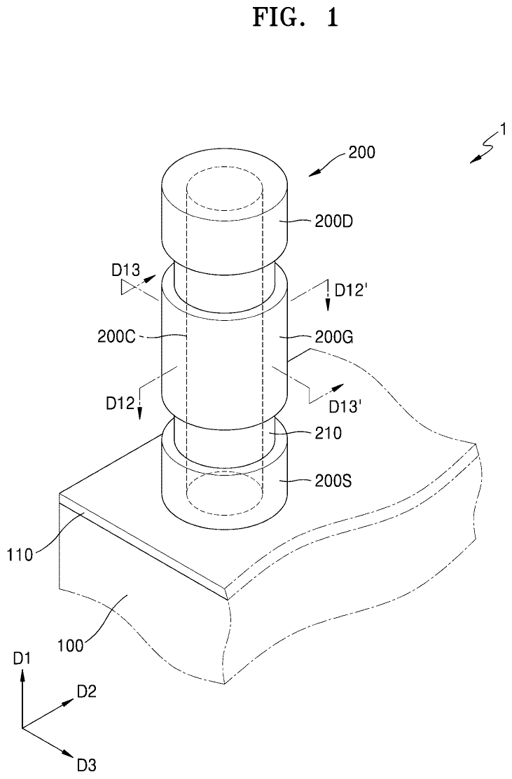

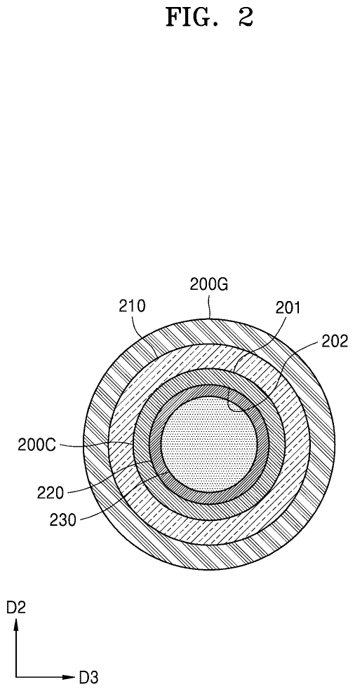

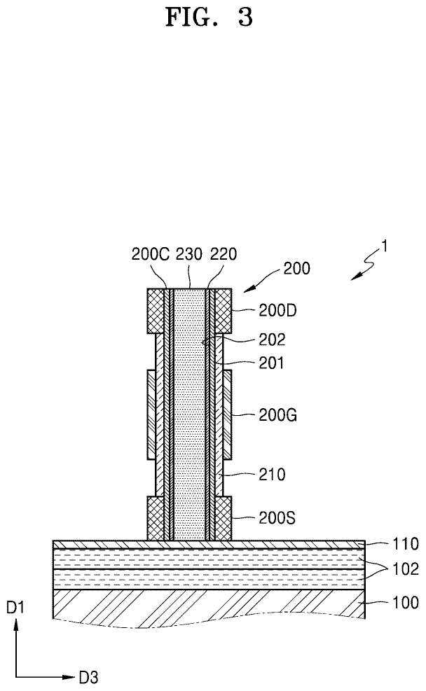

In the following embodiments, a first direction D1 may refer to a direction perpendicular to a substrate. A second direction D2 and a third direction D3 respectively may refer to two directions perpendicular to each other in a plane perpendicular to the first direction D1. FIG. 1 is a schematic perspective view of a semiconductor device 1 according to an embodiment. FIG. 2 is a cross-sectional view of the semiconductor device 1 of FIG. 1 taken along line D13-D13′, according to an embodiment. FIG. 3 is a cross-sectional view of the semiconductor device 1 of FIG. 1 taken along line D12-D12′, according to an embodiment.

Referring to FIGS. 1 to 3, the semiconductor device 1 may include a substrate 100 and a vertical channel transistor structure 200 formed on the substrate 100. The vertical channel transistor structure 200 may include a vertical channel 200C having a tube shape, or a hollow rod shape extending in a vertical direction, for example, a first direction D1. An outer insulating layer 210 may be arranged on an outer circumferential surface of the vertical channel 200C. A gate electrode 200G may face the vertical channel 200C with the outer insulating layer 210 arranged therebetween. An inner insulating layer 220 may be arranged on an inner circumferential surface 202 of the vertical channel 200C. A conductive layer 230 may be arranged in the vertical channel 200C. The conductive layer 230 may face the vertical channel 200C with the inner insulating layer 220 arranged therebetween. A source electrode 200S and a drain electrode 200D may be electrically connected to the vertical channel 200C. For example, the source electrode 200S and the drain electrode 200D may respectively be electrically connected to both ends of the vertical channel 200C in the first direction D1. Accordingly, the vertical channel transistor structure 200 may be formed. The vertical channel transistor structure 200 may form a unit device of the semiconductor device 1.

The substrate 100 may be an insulating substrate. The substrate 100 may be a semiconductor substrate on which an insulating layer 110 is formed. The semiconductor substrate may include, for example, Si, Ge, SiGe, or group III-V semiconductor materials, etc. The substrate 100 may be, for example, a silicon substrate on which a silicon oxide layer is formed; however, the disclosure is not limited thereto. A metallization layer 102 may be arranged on the substrate 100. The metallization layer 102 may include a plurality of metallization layers. A shape of the metallization layer 102 is not particularly limited. The metallization layer 102 may be between the substrate 100 and the insulating layer 110.

The vertical channel 200C may have a tube shape extending in the first direction D1, which is the vertical direction, from the substrate 100. In the embodiment, the cross-section of the vertical channel 200C that is perpendicular to the first direction D1 may have a circular shape. The cross-section of the vertical channel 200C that is perpendicular to the first direction D1 may have substantially circular shape, for example, a donut shape with a hole in the middle. Accordingly, the vertical channel 200C of the embodiment may have a cylindrical tube shape. The thickness of the vertical channel 200C may be several nanometers to tens of nanometers. Accordingly, the vertical channel 200C may have a tube shape (a nano-sheet shape, or a nano-tube shape).

The vertical channel 200C may include a two-dimensional (2D) semiconductor material. The 2D semiconductor material may include, for example, a transition metal dichalcogenide (TMD) material, graphene, black phosphorus, amorphous boron nitride, or phosphorene.

The vertical channel 200C may include a TMD material. The vertical channel 200C may use a 2D material, for example, a TMD material to implement a short channel length when the semiconductor device 1 is applied as a field effect transistor (FET). The channel length refers to a length of a channel in a direction in which a source electrode and a drain electrode are apart from each other. According to the recent tendency of miniaturization of electronic apparatuses, the channel length has decreased. When the channel length decreases, issues due to short channel effects may occur. To limit and/or prevent such issues and effectively reduce the channel length, it may be advantageous to maintain a thin channel thickness. In other words, the thinner the thickness of the channel is, the shorter the minimum implementable channel length may be. The 2D semiconductor material, for example, a TMD material may have excellent electrical characteristics, and even when the 2D semiconductor material has a nano-scale thickness, the characteristics may not change significantly, and high mobility may be maintained. That is, the TMD material is a 2D material formed by van der Waals force and has an advantage of retaining device characteristics even in a single layer. The TMD material may have a mono-layer or multi-layer structure. Each layer of the TMD material included in the channel may have a thickness of atomic level.

For example, the thickness of the vertical channel 200C may be 10 nm or less, 5 nm or less, or 3 nm or less (e.g., greater than 0 nm and less than or equal to 3 nm). The thickness of the vertical channel 200C is not limited thereto, and may be thinner. The width of the vertical channel 200C, for example, a diameter of the vertical channel 200C may be properly determined considering the thickness of the inner insulating layer 220 and the conductive layer 230 described above. However, the disclosure is not limited thereto. The thinner the thickness of the vertical channel 200C is, the shorter the length of the vertical channel 200C may be. For example, the vertical channel 200C may include a TMD material having one to ten layer(s).

The TMD material may include, for example, at least one transition metal from among Mo, W, Nb, V, Ta, Ti, Zr, Hf, Tc, and Re and at least one chalcogen element from among S, Se, and Te. The TMD material may be represented by, for example, MX₂ where M represents a transition metal, and X represents a chalcogen element. For example, M may be Mo, W, Nb, V, Ta, Ti, Zr, Hf, Tc, Re, etc., and X may be S, Se, T, etc. Accordingly, the TMD material may include MoS₂, MoSe₂, MoTe, WS₂, WSe₂, WTe₂, ZrS₂, ZrSe₂, HfS₂, HfSe₂, NbSe₂, ReSe, etc.

However, the aforementioned materials are just an example, and other materials may be used as a TMD material. For example, the TMD material may not be represented by MX₂. In this case, for example, the TMD material may include CuS which is a compound of Cu, a transition metal, and S, a chalcogen element. The TMD material may be chalcogenide material including a non-transition metal. The non-transition metal may include, for example, Ga, In, Sn, Ge, Pb, etc. In this case, the TMD material may include a compound of a non-transition metal such as Ga, In, Sn, Ge, Pb, etc. and a chalcogen element such as S, Se, and Te. For example, the TMD material may include SnSe₂, GaS, GaSe, GaTe, GeSe, In₂Se₃, InSnS₂, etc.

In an embodiment, the vertical channel 200C may include other depositable semiconductor materials. For example, the vertical channel 200C may include polysilicon.

In an embodiment, the vertical channel 200C may include an oxide semiconductor of which conductivity may be controlled through doping. For example, the oxide semiconductor may include a metal oxide semiconductor.

The vertical channel 200C may be, for example, a p-channel or an n-channel. To this end, the vertical channel 200C may be doped with a p-type dopant or an n-type dopant, when necessary. The p-type dopant or the n-type dopant may be doped to the vertical channel 200C through ion implantation or chemical doping.

The source electrode 200S and the drain electrode 200D may be arranged apart from each other in the first direction D1. The source electrode 200S may be electrically connected to one end of the vertical channel 200C in the first direction D1, for example, a lower end. The drain electrode 200D may be electrically connected to the other end of the vertical channel 200C in the first direction D1, for example, an upper end. The source electrode 200S and the drain electrode 200D may be in edge contact or surface contact with the vertical channel 200C. In the embodiment, the source electrode 200S and the drain electrode 200D may be in surface contact with the vertical channel 200C. The source electrode 200S and the drain electrode 200D may at least partially surround an outer circumferential surface 201 of the vertical channel 200C. In the embodiment, the source electrode 200S and the drain electrode 200D may completely surround the outer circumferential surface 201 of the vertical channel 200C.

The outer insulating layer 210 may insulate the source electrode 200S and the drain electrode 200D. The outer insulating layer 210 may be formed in at least a part of an area between the source electrode 200S and the drain electrode 200D, of the outer circumferential surface 201 of the vertical channel 200C. In the embodiment, the outer insulating layer 210 may completely cover the outer circumferential surface 201 of the vertical channel 200C between the source electrode 200S and the drain electrode 200D. The gate electrode 200G may be arranged between the source electrode 200S and the drain electrode 200D in the first direction D1. The gate electrode 200G may face the vertical channel 200C, for example, the outer circumferential surface 201 of the vertical channel 200C with the outer insulating layer 210 arranged therebetween. The outer insulating layer 210 may function as a gate insulating film between the gate electrode 200G and the vertical channel 200C. The gate electrode 200G may at least partially cover the outer circumferential surface 201 of the vertical channel 200C. According to the embodiment in which the vertical channel 200C having a tube shape is employed, the gate electrode 200G may surround the outer circumferential surface 201 of the vertical channel 200C. According to such structure, a facing area between the gate electrode 200G and the vertical channel 200C may increase, and a greater amount of current may flow through the vertical channel 200C. In addition, a leakage current may be limited and/or suppressed, and a great driving current may be obtained even with the gate electrode 200G having a short length. That is, by increasing the facing area between the gate electrode 200G and the vertical channel 200C, the channel control ability of the gate electrode 200G may be improved, and the effects of reduced short channel effect, improved driving current, and limited and/or suppressed leakage current may be achieved.

The inner insulating layer 220 may be formed on the inner circumferential surface 202 of the vertical channel 200C. The conductive layer 230 may be arranged in the vertical channel 200C. The conductive layer 230 may face the vertical channel 200C with the inner insulating layer 220 arranged therebetween. The conductive layer 230 may be arranged in an inner area of the vertical channel 200C, e.g., an area at least facing the gate electrode 200G. The conductive layer 230 may be electrically connected to the gate electrode 200G and may be in an electrical floating state. According to such structure, the vertical channel 200C may be interposed between the gate electrode 200G and the conductive layer 230. As the conductive layer 230 functions as an active gate electrode or at least a floating gate, the facing area between the vertical channel 200C and the gate electrode 200G may further increase. Accordingly, the channel control ability of the gate electrode 200G may be further improved, and the effects of reduced short channel effect, improved driving current, and limited and/or suppressed leakage current may be achieved.

The source electrode 200S, the drain electrode 200D, the gate electrode 200G, and the conductive layer 230 may include a metal material or a conductive oxide. The metal material may include, for example, at least one selected from Au, Ti, TiN, TaN, W, Mo, WN, Pt, and Ni. The conductive oxide may include, for example, indium tin oxide (ITO), indium zinc oxide (IZO), etc. The source electrode 200S, the drain electrode 200D, the gate electrode 200G, and the conductive layer 230 may include polysilicon or single-crystal silicon. The outer insulating layer 210 and the inner insulating layer 220 may include, for example, a metal oxide dielectric material. The metal oxide dielectric material may be, for example, an oxide of Al, La, Ti, Zr, Hf, Mg, Ge, Y, Lu, or Sr.

Accordingly, the vertical channel transistor structure 200 having a FET structure employing the vertical channel 200C having a tube shape may be formed.

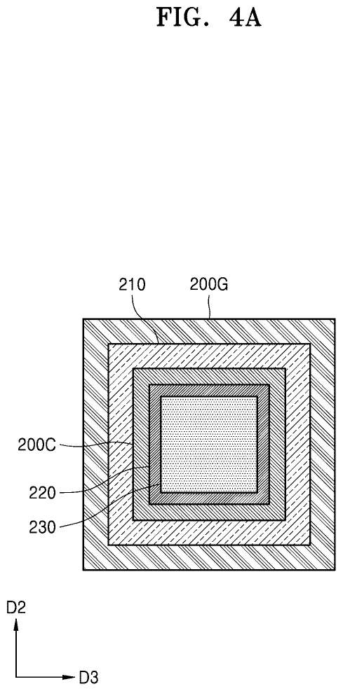

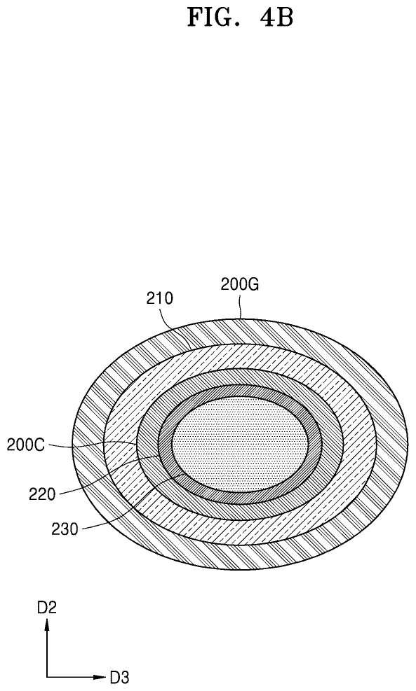

Although the foregoing embodiments describe the vertical channel 200C having a cylindrical tube shape, the shape of the vertical channel 200C is not limited thereto. FIGS. 4A and 4B illustrate examples of a cross-section of the vertical channel 200C. The vertical channel 200C may have various cross-sections. For example, as illustrated in FIG. 4A, the cross-section of the vertical channel 200C that is perpendicular to the first direction D1 may be tetragonal. In this case, the vertical channel 200C may have a square tube shape. As illustrated in FIG. 4B, the cross-section of the vertical channel 200C that is perpendicular to the first direction D1 may be elliptical. In this case, the vertical channel 200C may have an elliptic cylindrical tube shape. The cross-sections of the vertical channel 200C illustrated in FIGS. 4A and 4B are provided as an example. The vertical channel 200C may have various cross-sectional shape such as a polygon, an atypical closed figure including curves and straight lines, etc., when necessary.

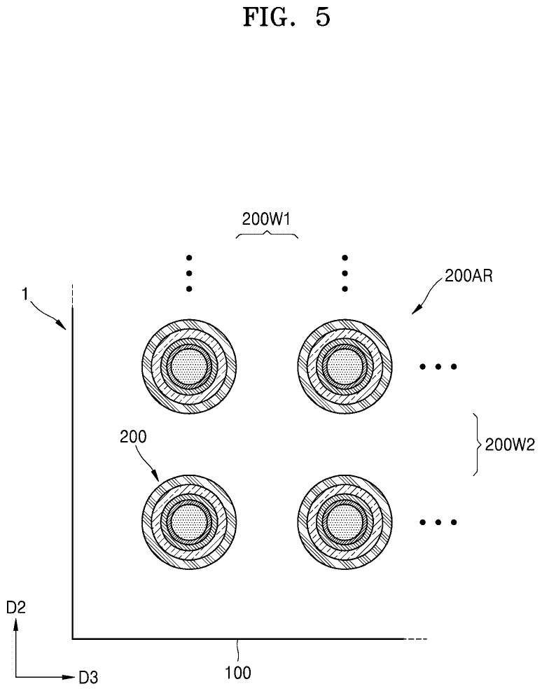

In some embodiment, a semiconductor device may include a vertical channel transistor array including a plurality of vertical channel transistor structures arranged in a two-dimensional (2D) manner on a plane perpendicular to the first direction. At least one vertical channel transistor structure, for example, each vertical channel transistor structure among the plurality of vertical channel transistor structures may include the tube shape vertical channel. FIG. 5 is a schematic plan view of the semiconductor device 1 according to an embodiment. Referring to FIG. 5, the semiconductor device 1 may include a vertical channel transistor array 200AR. The vertical channel transistor array 200AR may include a plurality of vertical channel transistor structures 200 arranged in a 2D manner on a plane perpendicular to the first direction D1. As the vertical channel transistor structure 200 includes the vertical channel 200C having a tube shape, a number of vertical channel transistor structures 200 may be arranged in a given area while securing a wide facing area with the gate electrode 200G and the vertical channel 200C. Accordingly, unit devices (the vertical channel transistor structures 200) having a high driving current and channel control ability may be arranged at a high integration degree. A wiring structure may be arranged in areas 200W1 and 200W2 between the vertical channel transistor structures 200.

By combining a capacitor with each of the vertical channel transistor structures 200, the semiconductor device 1 may be implemented as a memory device having a 1T1C structure. By combining a ferroelectric material with each of the vertical channel transistor structures 200, the semiconductor device 1 may be implemented as, for example, ferroelectric random access memory (FRAM). In this case, a plurality of word lines extending in the second direction D2 may be provided in the area 200W1, and a plurality of bit lines extending in the third direction D3 may be provided in the area 200W2.

The vertical channel transistor structure 200 may be an n-FET or a p-FET. In addition, by forming two adjacent vertical channel transistor structures 200 respectively as an n-FET and a p-FET, a CFET may be implemented.

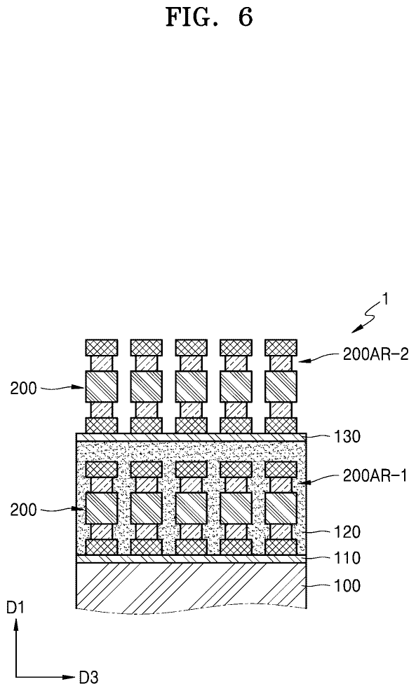

FIG. 6 is a schematic side view of the semiconductor device 1 according to an embodiment. Referring to FIG. 6, the semiconductor device 1 may include a plurality of vertical channel transistor arrays stacked in the vertical direction, e.g., the first direction D1, with an isolation layer 120 arranged therebetween. As an embodiment, FIG. 6 illustrates two vertical channel transistor arrays (200AR-1 and 200AR-2). The vertical channel transistor array 200AR-1 may be formed on the substrate 100. The isolation layer 120 may cover the vertical channel transistor array 200AR-1. An insulating layer 130 may be provided on the isolation layer 120, and the vertical channel transistor array 200AR-2 may be stacked on the insulating layer 130. The insulating layer 130 may be identical to, for example, the insulating layer 110. The isolation layer 120 may include an insulating material. By such structure, the integration degree of the semiconductor device 1 may be further improved.

While FIG. 6 illustrates a semiconductor device 1 where the vertical channel transistor structures 200 in the arrays 200AR-1 and 200AR-2 are separated from each other, example embodiments are not limited thereto. In an alternative embodiment, the lower electrode (e.g., source electrode 200S) of a corresponding vertical channel transistor structure 200 in the vertical channel transistor array 200AR-2 may be electrically connected to the upper electrode (e.g., drain electrode 200D) of a corresponding vertical channel transistor structure 200 therebelow in the vertical channel transistor array 200AR-1, or one electrode may be configured to function as the lower electrode in the corresponding vertical channel transistor structure 200 of the vertical channel transistor array 200AR-2 and the upper electrode of the corresponding vertical channel transistor structure 200 therebelow in the vertical channel transistor array 200AR-1, and the insulating layer 130 optionally may be omitted.

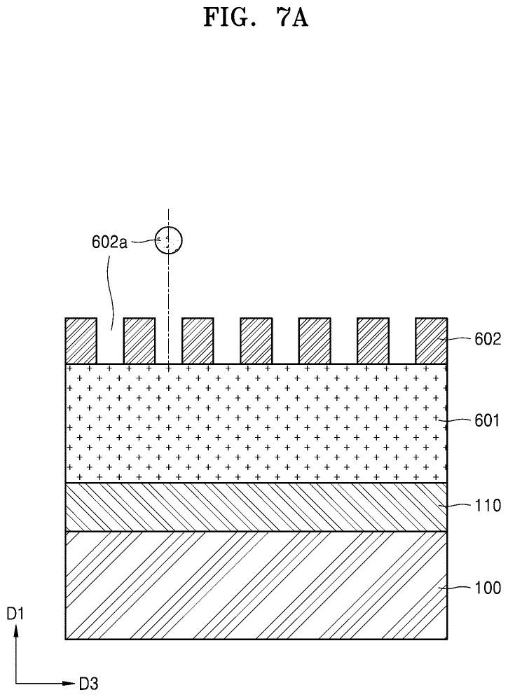

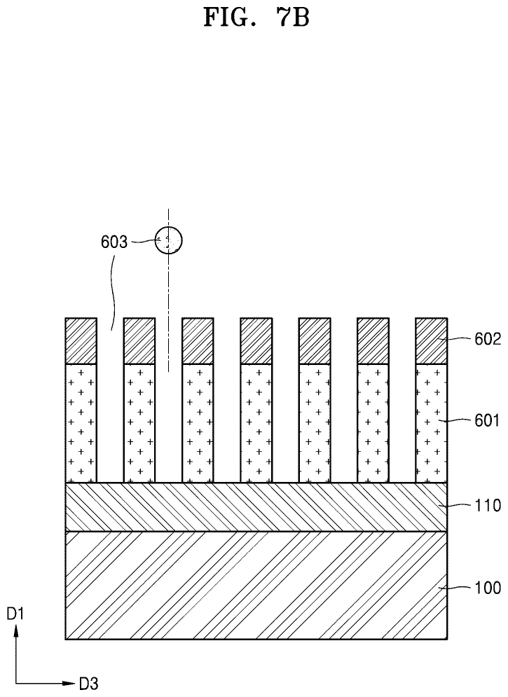

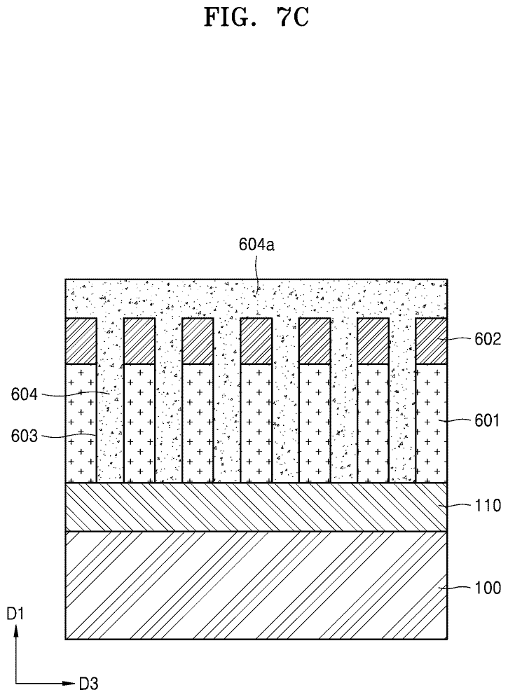

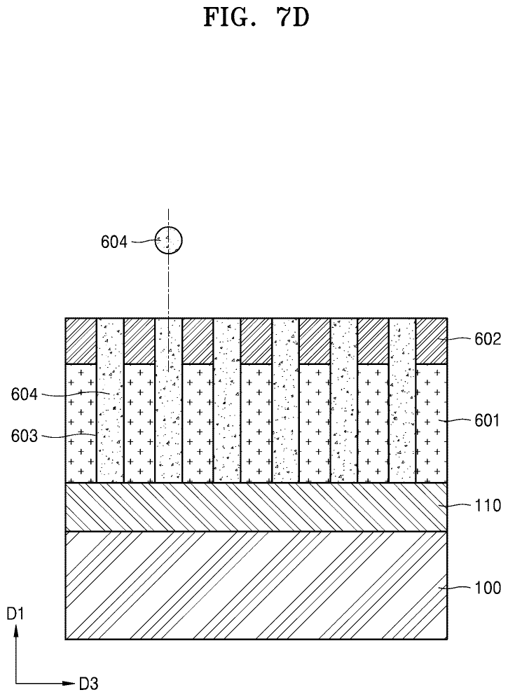

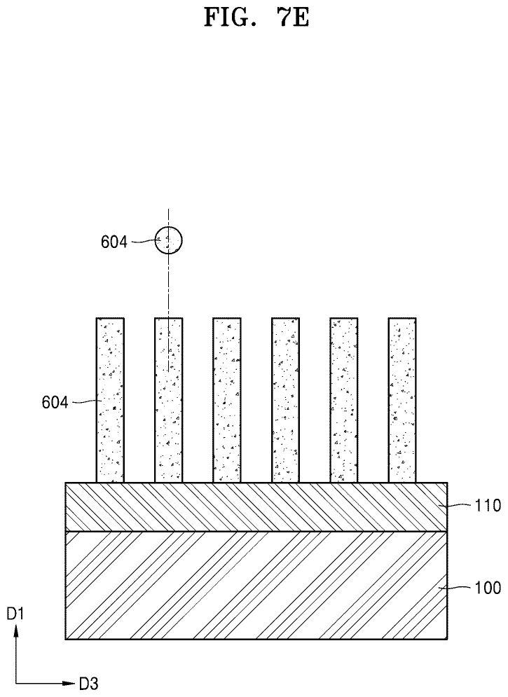

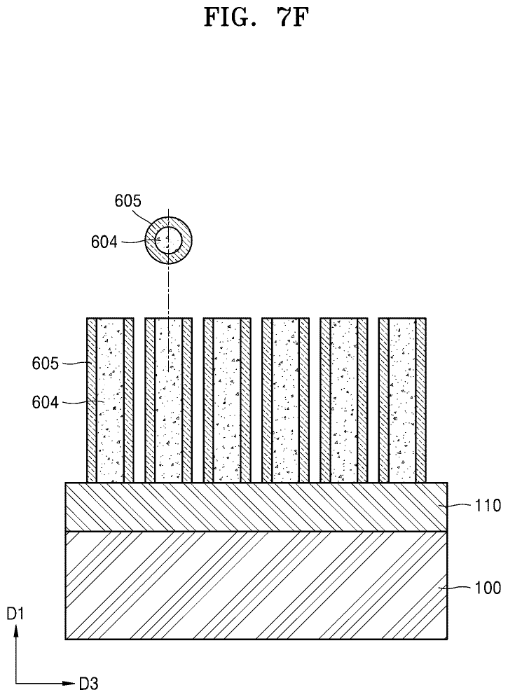

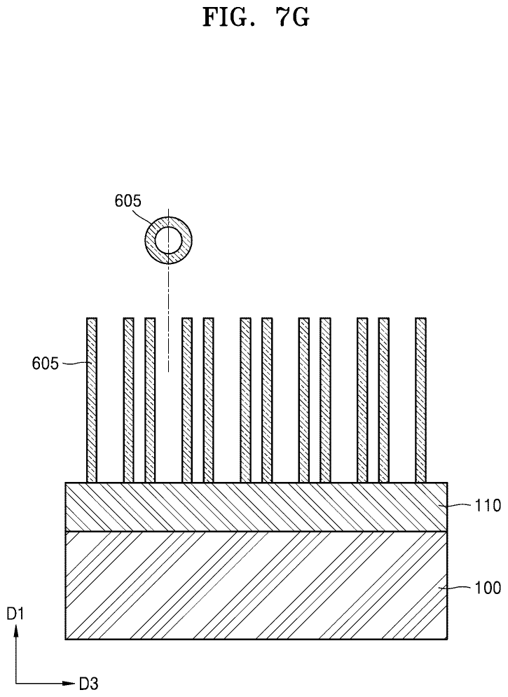

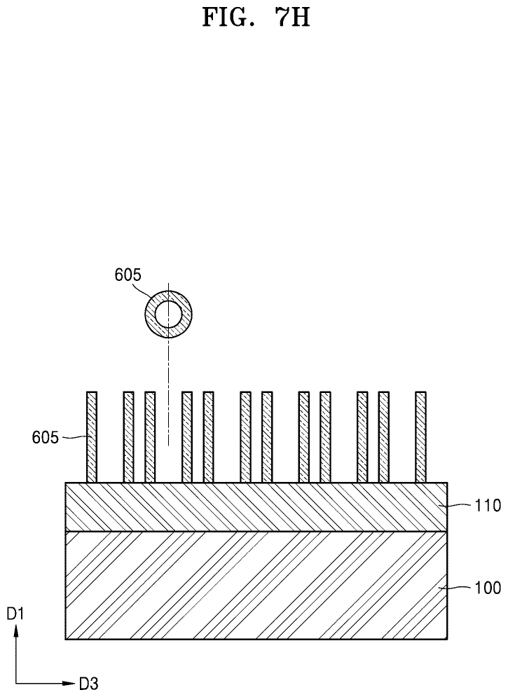

FIGS. 7A to 7H are diagrams each illustrating an example of a manufacturing method of the vertical channel 200C having a tube shape. The manufacturing method of the vertical channel 200C having a cylindrical tube shape is to be described in the embodiment.

First, referring to FIG. 7A, the substrate 100 may be prepared. The substrate 100 may be, for example, an insulating substrate. In this case, the insulating layer 110 may be omitted. The substrate 100 may be a semiconductor substrate, for example, a semiconductor substrate including Si, Ge, SiGe, or group III-V semiconductor materials. In this case, the insulating layer 110 may be arranged on the surface of the substrate 100 and the conductive layer 102 optionally may be provided between the substrate 100 and the insulating layer 110. The substrate 100 may be a silicon substrate on which the insulating layer 110 including a silicon oxide is formed. A pattern layer 601 may be formed on an upper surface of the insulating layer 110. The pattern layer 601 may include, for example, SOH. A mask layer 602 having a plurality of openings 602a may be formed on an upper surface of the pattern layer 601. The shape of the openings 602a may correspond to the shape of the vertical channel 200C. In the embodiment, the openings 602a may have a circular shape. The mask layer 602 may include, for example, SiON. The mask layer 602 may be formed by, for example, a photolithography method.

The pattern layer 601 may be etched through the plurality of openings 602a. Then, a plurality of slots 603 having a cylindrical shape may be formed in the pattern layer 601 as illustrated in FIG. 7B. The etching process may be, for example, a wet etching process. As illustrated in FIG. 7C, a plurality of supporters 604 may be formed inside the slots 603 by, for example, an atomic layer deposition (ALD) method. The supporter 604 may include an oxide, for example, SiO₂. The oxide may also be formed on the upper surface of the mask layer 602. For example, an oxide 604a formed on the upper surface of the mask layer 602 may be removed by, for example, a dry etching process. By doing so, as illustrated in FIG. 7D, the plurality of supporters 604 filling the insides of the plurality of slots 603 may be formed. The mask layer 602 and the pattern layer 601 may be removed by an etching process. Then, as illustrated in FIG. 7E, the plurality of supporters 604 having a cylindrical shape extending in the vertical direction may be left on the substrate 100.

A channel material layer 605 may be formed by growing a channel material in the first direction D1 from the surface of the substrate 100 along the outer circumferential surface of the plurality of supporters 604 having a cylindrical shape as illustrated in FIG. 7F. This process may be performed by, for example, the ALD process. The channel material may be, for example, a TMD material. The TMD material may include, for example, one transition metal from among Mo, W, Nb, V, Ta, Ti, Zr, Hf, Tc, and Re and one chalcogen element from among S, Se, and Te. The TMD material may be represented by, for example, MX₂ where M represents a transition metal, and X represents a chalcogen element. For example, M may be Mo, W, Nb, V, Ta, Ti, Zr, Hf, Tc, Re, etc., and X may be S, Se, T, etc. Accordingly, the TMD material may include at least one of MoS₂, MoSe₂, MoTe₂, WS₂, WSe₂, WTe₂, ZrS₂, ZrSe₂, HfS₂, HfSe₂, NbSe₂, and ReSe₂, etc. As described above, the TMD material may include a material that is not represented by MX₂, for example, CuS, and may be a chalcogenide material including a non-transition metal. The channel material may be polysilicon or an oxide semiconductor material. In the embodiment, a TMD material may be used as the channel material.

The plurality of supporters 604 may be removed by, for example, the wet etching process. By doing so, as illustrated in FIG. 7G, a plurality of channel material layers 605 having a cylindrical tube shape may be formed on the substrate 100.

Next, when necessary, lowing of the height of the channel material layer 605 may be performed. For example, the upper portion of the channel material layer 605 may be etched. Then, as illustrated in FIG. 7H, the upper portion of the channel material layer 605 may be removed, and the height of the channel material layer 605 having a cylindrical tube shape may be reduced. The channel material layer 605 may correspond to the vertical channel 200C illustrated in FIGS. 1 to 6.

Although it is not shown in the drawings, by forming the source electrode 200S, the drain electrode 200D, the outer insulating layer 210, the inner insulating layer 220, the gate electrode 200G, and the conductive layer 230, the vertical channel transistor structure 200 or the vertical channel transistor array 200AR illustrated in FIGS. 1 to 5 may be formed. A process of forming electrodes may be performed by widely known processes. In addition, in the state illustrated in FIG. 7H, after forming the vertical transistor array 200AR-1 by forming the electrodes, the isolation layer 120 may be covered by the vertical transistor array 200AR-1, and then by performing the aforementioned process thereon, the vertical transistor array 200AR-2 may be formed. By doing so, the embodiment of the semiconductor device 1 illustrated in FIG. 6 may be implemented.

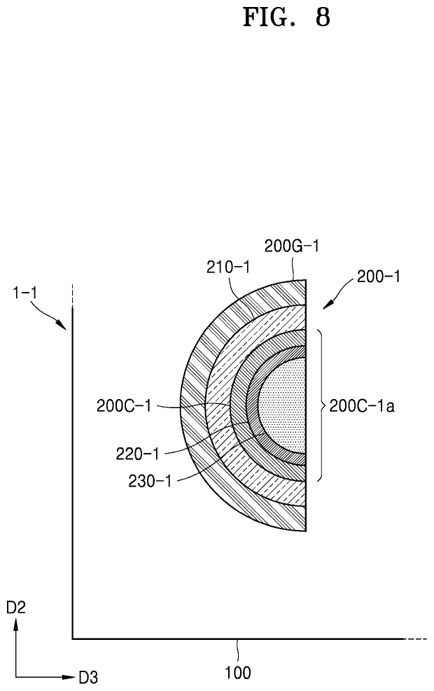

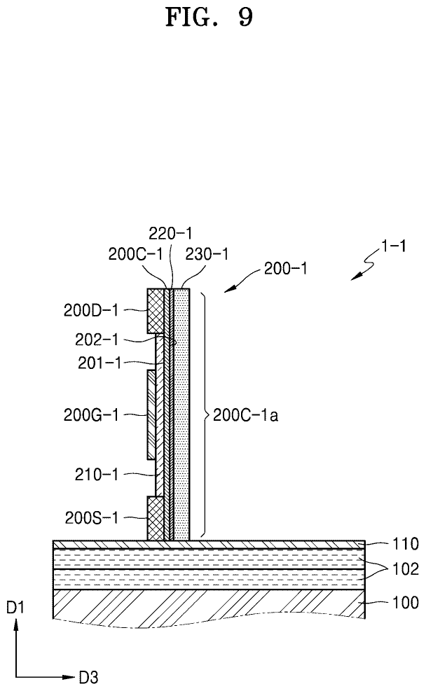

FIG. 8 is a schematic cross-sectional view of a semiconductor device 1-1 according to an embodiment, which corresponds to FIG. 2. FIG. 9 is a schematic cross-sectional view of the semiconductor device 1-1 according to an embodiment, which corresponds to FIG. 3. The semiconductor device 1-1 according to the embodiment may be different from the semiconductor device 1 described above in relation to FIGS. 1 to 6 in that a lateral portion perpendicular to the first direction D1 is open. Hereinafter, the embodiments is described focusing on the aforementioned difference, and the descriptions on the semiconductor device 1 illustrated in FIGS. 1 to 6 are applicable to the semiconductor device 1-1 of the embodiment as long as there is no contradiction. Referring to FIGS. 8 and 9, the semiconductor device 1-1 may include a substrate 100 and a vertical channel transistor structure 200-1 formed on the substrate 100.

The substrate 100 may be an insulating substrate. The substrate 100 may be a semiconductor substrate on which an insulating layer 110 is formed. The semiconductor substrate may include, for example, Si, Ge, SiGe, or group III-V semiconductor materials, etc. The substrate 100 may be, for example, a silicon substrate on which a silicon oxide layer is formed; however, the disclosure is not limited thereto. A metallization layer 102 may be arranged on the substrate 100. The metallization layer 102 may include a plurality of metallization layers. A shape of the metallization layer 102 is not particularly limited. The metallization layer 102 may be between the substrate 100 and the insulating layer 110.

The vertical channel transistor structure 200-1 may include a vertical channel 200C-1. The vertical channel 200C-1 may have a tube shape, or a hollow rod shape extending in the first direction D1, which is the vertical direction, from the substrate 100. The vertical channel 200C-1 may include an opening 200C-1A on a lateral surface perpendicular to the first direction D1. In the embodiment, the opening 200C-1a may be formed on the lateral surface of the vertical channel 200C-1 in the third direction D3. The opening 200C-1a may be formed across the length of vertical channel 200C-1 in the first direction D1. In the embodiment, the cross-section of the vertical channel 200C-1 that is perpendicular to the first direction D1 may have a semicircular shape. The thickness of the vertical channel 200C-1 may be several nanometers to tens of nanometers. Accordingly, the vertical channel 200C-1 may have a semicylindrical tube shape (nano-sheet shape, or nano-tube shape) including the opening 200C-1a. The channel material forming the vertical channel 200C described above may be applicable to a channel material forming the vertical channel 200C-1.

A source electrode 200S-1 and a drain electrode 200D-1 may be electrically connected to the vertical channel 200C-1. The source electrode 200S-1 and the drain electrode 200D-1 may be arranged apart from each other in the first direction D1. The source electrode 200S-1 may be electrically connected to one end of the vertical channel 200C-1 in the first direction D1, for example, a lower end. The drain electrode 200D-1 may be electrically connected to the other end of the vertical channel 200C-1 in the first direction D1, for example, an upper end. The source electrode 200S-1 and the drain electrode 200D-1 may be in edge contact or surface contact with the vertical channel 200C-1. In the embodiment, the source electrode 200S-1 and the drain electrode 200D-1 may be in surface contact with the vertical channel 200C-1. The source electrode 200S-1 and the drain electrode 200D-1 may be in contact with an outer circumferential surface 201-1 of the vertical channel 200C-1.

An outer insulating layer 210-1 may be provided on the outer circumferential surface 201-1 of the vertical channel 200C-1. The outer circumferential surface 201-1 may be a surface opposite to the opening 200C-la. The outer insulating layer 210-1 may insulate the source electrode 200S-1 and the drain electrode 200D-1. The outer insulating layer 210-1 may be formed in at least a part of an area between the source electrode 200S-1 of the drain electrode 200D-1, of the outer circumferential surface 201-1 of the vertical channel 200C-1. In the embodiment, the outer insulating layer 210-1 may completely cover the outer circumferential surface 201-1 of the vertical channel 200C-1 between the source electrode 200S-1 and the drain electrode 200D-1.

A first gate electrode 200G-1 may be arranged between the source electrode 200S-1 and the drain electrode 200D-1 in the first direction D1. The first gate electrode 200G-1 may face the vertical channel 200C-1, for example, the outer circumferential surface 201-1 of the vertical channel 200C-1 with the outer insulating layer 210-1 arranged therebetween. The outer insulating layer 210-1 may function as a gate insulating film between the first gate electrode 200G-1 and the vertical channel 200C-1. The first gate electrode 200G-1 may at least partially cover the outer circumferential surface 201-1 of the vertical channel 200C-1.

An inner insulating layer 220-1 may be arranged on an inner circumferential surface 202-1 of the vertical channel 200C-1. The inner circumferential surface 202-1 may be a surface on a side of the opening 200C-la of the vertical channel 200C-1. A second gate electrode 230-1 may be arranged in the vertical channel 200C-1. The second gate electrode 230-1 may face the vertical channel 200C-1 with the inner insulating layer 220-1 arranged therebetween. The second gate electrode 230-1 may be arranged in an area at least facing the first gate electrode 200G-1, of an inner area of the vertical channel 200C-1. The first gate electrode 200G-1 and the second gate electrode 230-1 may face each other with the vertical channel 200C-1 arranged therebetween. The second gate electrode 230-1 may be an active gate electrode which is electrically connected to the first gate electrode 200G-1 or to which a voltage is applied independently.

Descriptions provided in relation to the materials forming the source electrode 200S, the drain electrode 200D, the gate electrode 200G, the conductive layer 230, the outer insulating layer 210, and the inner insulating layer 220 may be respectively applied to the materials forming the source electrode 200S-1, the drain electrode 200D-1, the first gate electrode 200G-1, the second gate electrode 230-1, the outer insulating layer 210-1, and the inner insulating layer 220-1.

According to the above, the vertical channel transistor structure 200-1 including the vertical channel 200C-1, the outer insulating layer 210-1, the first gate electrode 200G-1, the inner insulating layer 220-1, the second gate electrode 230-1, the source electrode 200S-1, and the drain electrode 200D-1 may be formed. The vertical channel transistor structure 200-1 may form a unit device of the semiconductor device 1-1. According to such structure, as the first and second gate electrodes 200G-1 and 230-1 functions as an active gate electrode, the facing area between the vertical channel 200C-1 and the gate electrode may increase. Accordingly, the channel control ability of the gate electrode may be further improved, and the effects of reduced short channel effect, improved driving current, and limited and/or suppressed leakage current may be achieved.

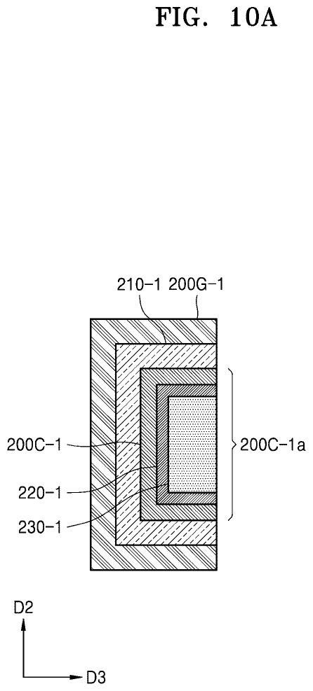

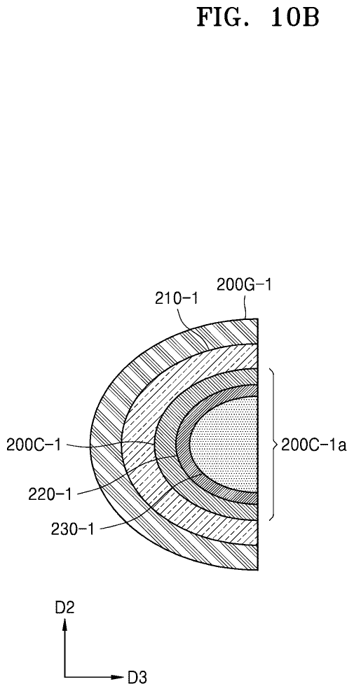

Although the foregoing embodiments describe the vertical channel 200C-1 having a semicylindrical tube shape, the shape of the vertical channel 200C-1 is not limited thereto. FIGS. 10A and 10B illustrate examples of a cross-section of the vertical channel 200C-1. The vertical channel 200C-1 may have various cross-sections. For example, as illustrated in FIG. 10A, the cross-section of the vertical channel 200C-1 that is perpendicular to the first direction D1 may have a semi-tetragonal shape having the opening 200C-1a on a lateral surface in the third direction D3. In this case, the vertical channel 200C-1 may have a square tube shape. As illustrated in FIG. 10B, the cross-section of the vertical channel 200C-1 that is perpendicular to the first direction D1 may have a semielliptical shape having the opening 200C-1a on the lateral surface in the third direction D3. In this case, the vertical channel 200C-1 may have an semielliptical cylindrical tube shape. The cross-sections of the vertical channel 200C-1 illustrated in FIGS. 10A and 10B are provided as an example. The vertical channel 200C-1 may have various cross-sectional shape such as a polygon, an atypical closed figure including curves and straight lines combined with the opening 200C-1a, etc., when necessary.

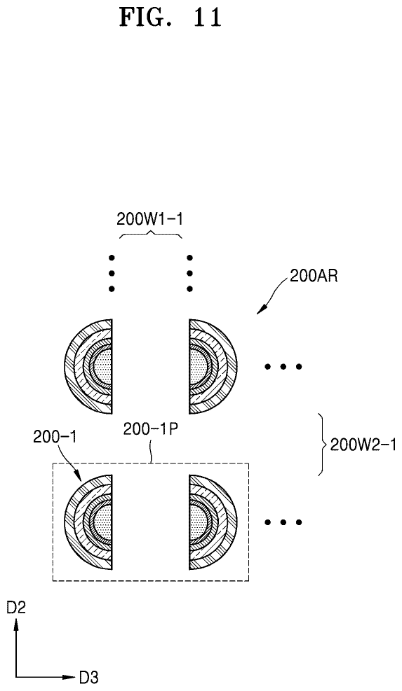

In some embodiment, a semiconductor device may include a vertical channel transistor array including a plurality of vertical channel transistor structures arranged in a two-dimensional (2D) manner on a plane perpendicular to the first direction. At least one vertical channel transistor structure, for example, each vertical channel transistor structure among the plurality of vertical channel transistor structures may include the tube shape vertical channel with the opening in the lateral surface thereof. FIG. 11 is a schematic plan view of the semiconductor device 1-1 according to an embodiment. Referring to FIG. 11, the semiconductor device 1-1 may include the vertical channel transistor array 200AR. The vertical channel transistor array 200AR may include a plurality of vertical channel transistor structures 200-1 arranged in a 2D manner on a plane perpendicular to the first direction D1. As the vertical channel transistor structure 200-1 includes the vertical channel 200C-1 having a tube shape including the opening 200C-1a, a number of vertical channel transistor structures 200-1 may be arranged in a given area while securing a wide facing area with the first and second gate electrodes 200G-1 and 230-1 and the vertical channel 200C-1. Accordingly, unit devices (the vertical channel transistor structures 200-1) having a high driving current and channel control ability may be arranged at a high integration degree. A wiring structure may be arranged in areas 200W1-1 and 200W2-1 between the vertical channel transistor structures 200-1.

As illustrated in FIG. 11, the vertical channel transistor array 200AR may include a plurality of pairs of vertical channel transistor structures 200-1P each including two vertical channel transistor structures 200-1 of which openings 200C-1a face each other. According to such structure, the lines may be easily connected to the second gate electrodes 230-1 of the two vertical channel transistor structures 200-1 forming a pair of vertical channel transistor structures 200-1P through the openings 200C-1a. In addition, as at least the width of the area 200W1-1 may become less than the width of the area 200W1 illustrated in FIG. 5, more vertical channel transistor structures 200-1 may be arranged in a given area.

The vertical channel transistor structure 200-1 may be an n-FET or a p-FET. By forming the vertical channels 200C-1 of the two vertical channel transistor structures 200-1 of a pair of vertical channel transistor structures 200-1P respectively as a p-channel and an n-channel, the pair of vertical channel transistor structures 200-1P may form a CFET.

By combining a capacitor with each of the vertical channel transistor structures 200-1, the semiconductor device 1-1 may be implemented as a memory device having a 1T1C structure. By combining a ferroelectric material with each of the vertical channel transistor structures 200-1, the semiconductor device 1-1 may be implemented as, for example, FRAM. In this case, a plurality of word lines extending in the second direction D2 may be provided in the area 200W1-1, and a plurality of bit lines extending in the third direction D3 may be provided in the area 200W2-1.

The semiconductor device 1-1 may include a plurality of vertical channel transistor arrays stacked in the vertical direction, e.g., the first direction D1, with an isolation layer 120 arranged therebetween. As an embodiment, FIG. 6 illustrates two vertical channel transistor arrays (200AR-1 and 200AR-2). The vertical channel transistor structure 200-1 described in relation to FIGS. 8 and 9 may be applied instead of the vertical channel transistor structure 200 constituting the two vertical channel transistor arrays (200AR-1 and 200AR-2) in FIG. 6. The vertical channel transistor arrays 200AR-1 may be formed on the substrate 100. The isolation layer 120 may cover the vertical channel transistor arrays 200AR-1. An insulating layer 130 may be provided on the isolation layer 120, and the vertical channel transistor arrays 200AR-2 may be stacked on the insulating layer 130. By such structure, the integration degree of the semiconductor device 1-1 may be further improved.

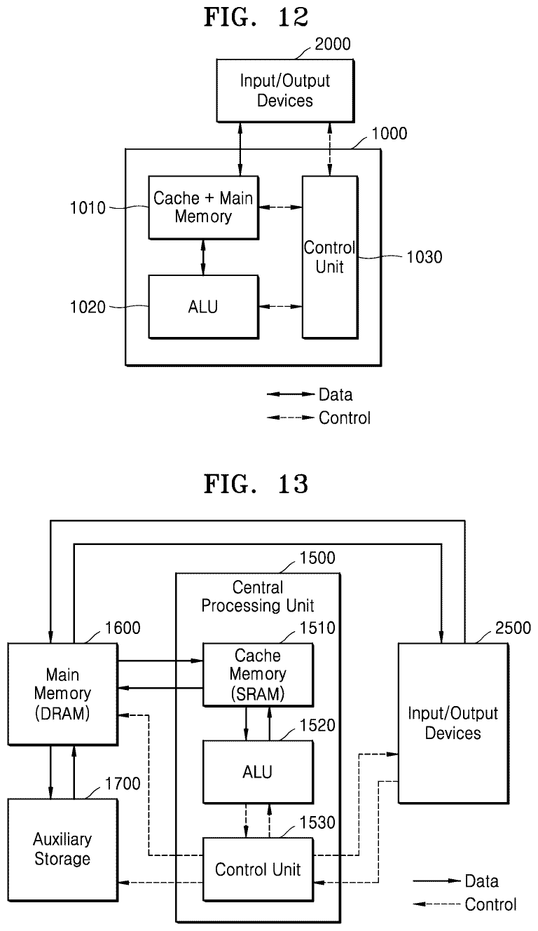

The semiconductor device 1 and the semiconductor device 1-1 according to the embodiments described above may be used for temporary storage of data in various electronic apparatuses. FIGS. 12 and 13 are each a conceptual diagram schematically illustrating a device architecture applicable to an electronic apparatus according to an embodiment.

Referring to FIG. 12, a device architecture 1000 may include a memory unit 1010, an arithmetic logic unit (ALU) 1020, and a control unit 1030. The memory unit 1010, the ALU 1020, and the control unit 1030 may be electrically connected. For example, the device architecture 1000 may be implemented as a single chip including the memory unit 1010, the ALU 1020, and the control unit 1030. Specifically, the memory unit 1010, the ALU 1020, and the control unit 1030 may be interconnected by a metal line on an on-chip and may communicate directly with each other. The memory unit 1010, the ALU 1020, and the control unit 1030 may be integrated on one substrate in a monolithic manner and constitute a single chip. One of more input/output devices 2000 (e.g., keyboard, display, etc.) may be connected to the device architecture 1000. The memory unit 1010 may include both of a main memory and a cache memory. The main memory may include the semiconductor device 1 and/or the semiconductor device 1-1 described above.

Referring to FIG. 13, a cache memory 1510, an ALU 1520, and a control unit 1530 may constitute a central processing unit 1500, and the cache memory 1510 may include static random access memory (SRAM). A main memory 1600 and an auxiliary storage 1700 may be provided separately and may be controlled by the CPU 1500. The main memory 1600 may include the semiconductor device 1 and/or the semiconductor device 1-1 described above. In some cases, the device architecture may be implemented in a form in which computing unit elements and memory unit elements are adjacent to each other on a single chip without separating sub-units. One of more input/output devices 2500 (e.g., keyboard, display, etc.) may be connected to the CPU 1500, main memory 1600, and auxiliary storage 1700.

According to the embodiments of the semiconductor device described above, by employing a tube shape vertical channel, the integration degree of unit devices may be improved.

According to the embodiments of the semiconductor device described above, by employing a tube shape vertical channel having an opening, the integration degree of unit devices may be improved.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A semiconductor device comprising:
a substrate;
a vertical channel having a tube shape extending from the substrate in a first direction perpendicular to a surface of the substrate;
an outer insulating layer on an outer circumferential surface of the vertical channel;
a gate electrode facing the vertical channel with the outer insulating layer between the gate electrode and the vertical channel;
an inner insulating layer on an inner circumferential surface of the vertical channel; and
a conductive layer in the vertical channel and facing the vertical channel with the inner insulating layer between the conductive layer and the vertical channel.

2. The semiconductor device of claim 1, wherein the gate electrode surrounds an outer circumference of the vertical channel.

3. The semiconductor device of claim 1, wherein the conductive layer faces the gate electrode.

4. The semiconductor device of claim 1, further comprising:
a source electrode and a drain electrode, wherein
the source electrode and the drain electrode are each electrically connected to the vertical channel and apart from each other in the first direction.

5. The semiconductor device of claim 4, wherein the gate electrode is between the source electrode and the drain electrode.

6. The semiconductor device of claim 1, wherein the vertical channel includes a transition metal dichalcogenide (TMD) material.

7. The semiconductor device of claim 6, wherein the TMD material includes at least one of MoS₂, MoSe₂, MoTe₂, WS₂, WSe₂, WTe₂, ZrS₂, ZrSe₂, HfS, HfSe₂, NbSe₂, and ReSe₂.

8. The semiconductor device of claim 1, wherein the vertical channel includes polysilicon.

9. The semiconductor device of claim 1, further comprising:
a source electrode and a drain electrode electrically connected to the vertical channel; and
a vertical channel transistor array including a plurality of vertical channel transistor structures, wherein
the plurality of vertical channel transistor structures are arranged in a two-dimensional (2D) manner on a plane perpendicular to the first direction, and
at least one vertical channel transistor structure among the plurality of vertical channel transistor structures includes the vertical channel, the outer insulating layer, the gate electrode, the inner insulating layer, the conductive layer, and the source electrode and the drain electrode electrically connected to the vertical channel.

10. The semiconductor device of claim 9, wherein the vertical channel transistor array includes a plurality of vertical channel transistor arrays stacked in the first direction with an isolation layer therebetween.

11. A semiconductor device comprising:
a substrate;
a vertical channel having a tube shape extending from the substrate in a first direction perpendicular to a surface of the substrate, a lateral surface of the vertical channel including an opening, the lateral surface of the vertical channel perpendicular to the first direction;
an outer insulating layer on an outer circumferential surface opposite to the opening of the vertical channel;
a first gate electrode facing the vertical channel with the outer insulating layer between the first gate electrode and the vertical channel;
an inner insulating layer on an inner circumferential surface on a side of the opening of the vertical channel; and
a second gate electrode facing the vertical channel with the inner insulating layer between the second gate electrode and the vertical channel.

12. The semiconductor device of claim 11, further comprising:
a source electrode and a drain electrode, wherein
the source electrode and the drain electrode are electrically connected to the vertical channel and spaced apart from each other in the first direction.

13. The semiconductor device of claim 12, wherein the first gate electrode is between the source electrode and the drain electrode.

14. The semiconductor device of claim 11, wherein the first gate electrode and the second gate electrode face each other with the vertical channel between the first gate electrode and the second gate electrode.

15. The semiconductor device of claim 11, wherein the vertical channel includes a transition metal dichalcogenide (TMD) material.

16. The semiconductor device of claim 15, wherein the TMD material includes at least one of MoS₂, MoSe₂, MoTe₂, WS₂, WSe₂, WTe₂, ZrS₂, ZrSe₂, HfS₂, HfSe₂, NbSe₂, and ReSe₂.

17. The semiconductor device of claim 11, wherein the vertical channel includes polysilicon.

18. The semiconductor device of claim 11, further comprising:
a source electrode and a drain electrode electrically connected to the vertical channel; and
a vertical channel transistor array including a plurality of vertical channel transistor structures arranged in a two-dimensional (2D) manner on a plane perpendicular to the first direction, wherein
at least one vertical channel transistor structure among the plurality of vertical channel transistor structures includes the vertical channel, the outer insulating layer, the first gate electrode, the inner insulating layer, the second gate electrode, and the source electrode and the drain electrode electrically connected to the vertical channel.

19. The semiconductor device of claim 18, wherein
the vertical channel transistor array includes a plurality of pairs of vertical channel transistor structures,
at least one of the plurality of pairs of vertical transistor structures includes a first vertical channel transistor having the opening and a second vertical channel transistor having the opening, and
the opening of the first vertical channel transistor faces the opening of the second vertical channel transistor.

20. The semiconductor device of claim 18, wherein the vertical channel transistor array includes a plurality of vertical channel transistor arrays stacked in the first direction with an isolation layer therebetween.
